(19) United States
(12) Patent Application Publication
(10) Pub. No.: US 2020/0028023 A1
(43) Pub. Date: Jan. 23, 2020

(54) METHOD FOR MANUFACTURING PHOTOVOLTAIC CELLS WITH A REAR SIDE POLYSILICON PASSIVATING CONTACT

(71) Applicant: Nederlandse Organisatie voor toegepast-natuurwetenschappelijk Onderzoek TNO, 's-Gravenhage, OT (NL)

(72) Inventors: Lambert Johan Geerligs, 's-Gravenhage (NL); Martien Koppes, 's-Gravenhage (NL); Yu Wu, 's-Gravenhage (NL); Maciej Stodolny, 's-Gravenhage (NL); Martijn Lenes, 's-Gravenhage (NL)

(73) Assignee: Nederlandse Organisatie voor toegepast-natuurwetenschappelijk Onderzoek TNO, 's-Gravenhage, OT (NL)

(21) Appl. No.: 16/470,998

(22) PCT Filed: Dec. 21, 2017
(86) PCT No.: PCT/NL2017/050862

§ 371 Date: Jun. 19, 2019

(30) Foreign Application Priority Data
Dec. 22, 2016 (NL) 2018042

(51) Int. Cl. H01L 31/18; H01L 31/0216; H01L 31/0368; H01L 31/0745

(52) U.S. Cl. CPC H01L 31/1868; H01L 31/02167; H01L 31/182; H01L 31/0745; H01L 31/03682

(57) ABSTRACT

A method for manufacturing a photovoltaic cell from a substrate (2) having a front side (4), a back side (6) and an edge (8). A carrier selective contact structure (4a) of a first type is provided on at least a part of the front side (4). A stack (10) having a thin oxide layer covered by a polysilicon layer is applied, wherein the stack (10) is applied to the back side (6) and the front side (4) of the substrate (2), and possibly also on edge (8). The stack (10) of thin oxide layer and polysilicon layer on the front side (4) is then removed.

### FIELD OF THE INVENTION

The present invention relates to a method of manufacturing a solar cell, in particular a solar cell having a rear side polysilicon passivating contact.

### BACKGROUND ART

U.S. Pat. No. 7,633,006 discloses a method for manufacturing a photovoltaic cell, wherein atmospheric pressure chemical vapour deposition (APCVD) is used to deposit various layers on top of a tunnel oxide layer on a back side of a silicon substrate. The tunnel oxide layer is deposited on both sides of the substrate (using e.g. an ozone oxidation process), and the front side tunnel oxide layer is removed in a later process step. The various layers include a polysilicon layer on top of a tunnel oxide layer, followed by a layer of p-type dopant and a layer of undoped silicon oxide. Such APCVD depositions are advantageous when only applying layers to one side of the substrate, such as in manufacturing back side contact solar cells.

### SUMMARY OF THE INVENTION

The present invention seeks to provide an improved method for manufacturing photovoltaic cells comprising rear side polysilicon passivating contacts. The method allows efficient use of manufacturing steps for protecting sides of the solar cell during various treatment steps.

According to the present invention, a method is provided for manufacturing a photovoltaic cell from a substrate having a front side, a back side and an edge (i.e. the circumferential side between front and back side). The method comprises providing a carrier selective contact structure of a first type (i.e. an electron or hole contact structure) on at least a part of the front side, and applying a stack having a thin oxide layer covered by a polysilicon layer. The stack is applied to the back side and the front side of the substrate, e.g. using a non-single sided process, and thus possibly also on the edge. At the back side the stack may be forming a rear side passivating contact structure of a second type (electron/hole). The method then further comprises removing (e.g. etching) the stack of thin oxide layer and polysilicon layer on the front side. It is noted that the term polysilicon as used herein encompasses amorphous silicon or polycrystalline silicon.

Through application of the thin oxide layer and polysilicon layer to the back side, edge as well as the front side of the substrate, a simplified manufacturing process is obtained wherein the applied stack acts as an effective barrier for subsequent treatment steps, in particular diffusion steps. Providing the stack of the present invention allows for a convenient “all side” manufacturing process, wherein an unwanted part of the stack on the front side of the substrate can be easily removed. It is noted that other elements, e.g. carbon, may be admixed to the polysilicon. The oxide layer may be a silicon oxide layer. Other elements, e.g. nitrogen, may be admixed to the oxide layer.

Another advantage of the method is that removal of the stack from the front side of the substrate allows to provide a good edge isolation, which in its turn minimizes reverse currents through the photovoltaic cell when in operation.

### SHORT DESCRIPTION OF DRAWINGS

The present invention will be discussed in more detail below, with reference to the attached drawings, in which

FIG. 1A to 1F depicts a schematic overview of the consecutive process steps for manufacturing a photovoltaic cell with a rear side polysilicon passivating contact in accordance with an embodiment of the present invention;

FIG. 2A to 2E depict a schematic overview of the consecutive process steps for manufacturing a photovoltaic cell with a rear side polysilicon passivating contact in accordance with a further embodiment of the present invention; and

FIG. 3A to 3E depict a schematic overview of the consecutive process steps for manufacturing a photovoltaic cell with a rear side polysilicon passivating contact in accordance with an even further embodiment of the present invention.

### DESCRIPTION OF EMBODIMENTS

When manufacturing a solar cell from a substrate through single sided processing steps, the manufacturing process must ensure that exposure of the other sides to the single sided processing step is minimized. In light of this there is a need for a method of manufacturing a solar cell that reduces the number of single sided processing steps and as such reduces the manufacturing complexity and associate costs for the solar cell.

The method of the present invention fulfils the above need by providing a method of manufacturing a solar cell by allowing for convenient “all side” processing steps whereby all sides of the substrate are subjected to the same treatment.

A doped polysilicon layer on top of a tunnel oxide layer forms a passivating contact on a silicon wafer, also known as a passivated contact or a carrier-selective contact. As is known in the art, contacts to crystalline silicon solar cells have to extract one type of carrier (electron or hole) and to at least a certain extent prevent the other type of carrier from entering the contact or recombining in the contact region (this prevention means there is some degree of passivation). That means that all contacts to solar cells advantageously are passivating or carrier-selective to some degree. The quality of a contact in preventing the other type of carrier from entering the contact and from recombining in the contact region is typically represented by the prefactor of the recombination current contributed by that contact J_{o,c}. A highly doped surface region of a wafer, that can e.g. be created by diffusion or implantation and anneal, and on which a metal contact is disposed, is one way of creating a contact for a solar cell that has some degree of carrier selectivity and passivation. This is the dominant way of creating contacts to crystalline silicon solar cells in the present industrial manufacturing of solar cells. A typical J_{o,c} of such a contact ranges from several hundred fA/cm² to several thousand fA/cm². Much better J_{o,c} of typically between one and several tens fA/cm² can be obtained by disposing on a crystalline silicon wafer a highly doped polysilicon layer on top of a tunnel oxide layer (the tunnel oxide layer being between the wafer and the doped polysilicon). On the polysilicon a metallic contact can be disposed while retaining such a low J_{o,c}. In the following description the terminology passivating contact as well as carrier selective contact is used, both describing such and other variations for creating a contact for a crystalline silicon solar cell.

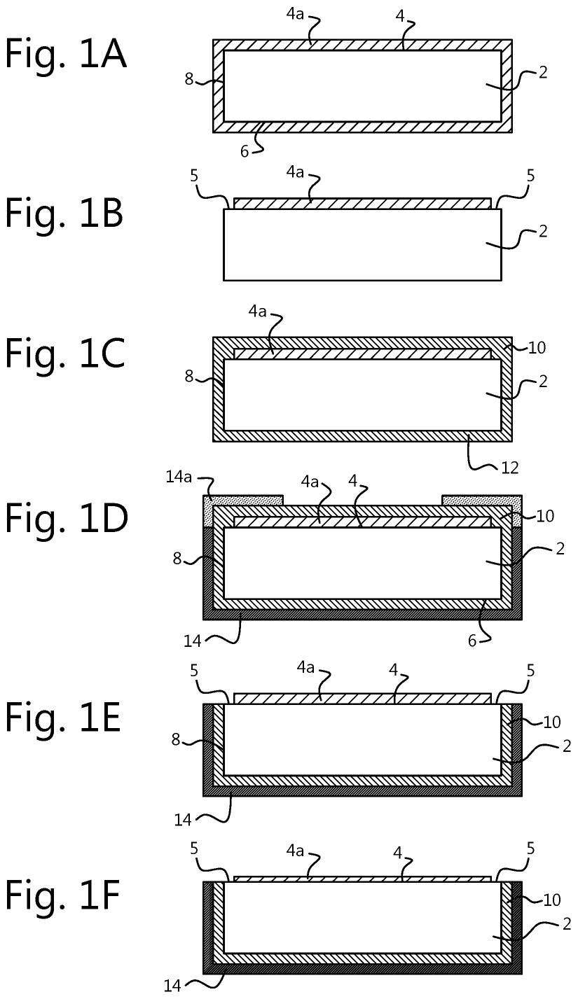

FIG. 1A to 1F each show consecutive steps of an embodiment of the method according to the present invention. In the embodiment step shown in FIG. 1A there is provided a substrate or wafer 2, e.g. a silicon substrate/wafer, having a front side 4, a back side 6 and an edge 8. In an embodiment, the edge 8 may be seen as a circumferential edge of the (semi-square) substrate 2, i.e. the edge 8 is the surface part of the substrate 2 connecting the front side 4 and back side 6.

As depicted in FIG. 1A, the substrate 2 may be a substrate or wafer 2 suitable for production of solar cells (e.g. having a textured front side or a textured front and back side). In one embodiment a carrier selective contact structure 4a of a first type is provided as a first polarity diffusion layer 4a on at least part of the front side 4, e.g. on both front side 4 and back side 6, before applying a stack 10 as described below with reference to FIG. 1C. The first polarity diffusion layer 4a may also be provided on (or into) all sides of the substrate/wafer 2, i.e. on the back side 6, edge 8, and front side 4, as shown in FIG. 1A (note that diffusion layer 4a would be within a surface layer part of the front side 4, back side 6, and edge 8) thereby allowing for all side treatment of the substrate 2. The carrier selective contact structure 4a may also be formed by or comprise an implanted layer, an implanted and annealed layer, deposition of BSG, or a thin oxide/doped polysilicon stack, as well as other carrier-selective contact layers which are known as such in the art, e.g. a metal oxide or metal oxide/oxide stack.

In an exemplary embodiment, the first polarity diffusion layer 4a may be a p+ diffusion layer. The p+ diffusion layer 4a may be envisaged as providing a p+ type front contact layer on the front side 4 of the substrate 2 as shown in FIG. 1a. The p+ diffusion may be applied through an all side treatment step and as such the p+ diffusion layer 4a will enclose the undiffused body of the substrate 2 as depicted. In an embodiment, the first polarity diffusion layer 4a may be obtained by depositing borosilicate glass (BSG) followed by an annealing step. E.g., the sheet resistance of the layer 4a may between about 50 and 500 Ohm/square, e.g. about 100 Ohm/square, with a surface dopant concentration above about 1E19 cm⁻³. For example the thickness of layer 4a may be between about 50 nm and 5 μm, e.g. about 1 μm.

As mentioned, the method embodiments of the present invention allow for a first polarity diffusion layer 4a to be provided to the substrate 2 before the stack 10 of a thin oxide layer and polysilicon layer is applied. In an embodiment, providing such a first polarity diffusion layer 4a may be accomplished in an all side treatment step so that the first polarity diffusion layer 4a is provided on the back side 6, edge 8 as well on the front side 4. In case the first diffusion layer 4a is to be used as a front contact layer, for example, an embodiment is provided wherein the first polarity diffusion layer 4a on the back side 6 and the edge 8 of the substrate 2 is removed using a single side etching step. The result of this step is clearly depicted in FIG. 1B, wherein only the front side 4 comprises the first polarity diffusion layer 4a. It is noted that this etching step is performed before the stack 10 is applied, again see the description with reference to FIG. 1C below.

In an advantageous embodiment, the first polarity diffusion layer 4a is further removed from a rim surface part 5 of the front side 4 of the substrate 2 using a single side etching step. The rim surface part 5 may be seen as a circumferential edge of the front side 4. The main reason for also removing the rim surface part 5 of the front side 4 (e.g. with a (circumferential) width of at most 2 mm) is to provide an improved edge isolation with respect to a doped layer 12 which is provided later in the manufacturing process (see description of FIG. 1C below). This method embodiment step is also depicted in FIG. 1B and also performed before the stack 10 is applied to the substrate 2.

The rim surface part 5 may further be passivated with a passivating coating such as a silicon oxide/silicon nitride stack or an aluminium oxide/silicon nitride stack.

According to the present invention, the method for manufacturing the solar cell comprises, as depicted in FIG. 1C, the step of applying or depositing a stack 10 of a thin oxide layer covered by a polysilicon layer on all sides of the substrate 2. That is, the stack 10 is deposited on the back side 6, the edge 8 as well as the front side 4 of the substrate 2. In an embodiment, the thin oxide is a thin silicon oxide layer providing excellent passivating properties. In a further embodiment the thin oxide layer has a thickness between 0.5 nm and 3 nm. The stack 10 may furthermore comprise amorphous silicon which crystallizes into polysilicon during subsequent processing. E.g., the thickness of the polysilicon may be between about 5 nm and 500 nm, e.g. about 100 nm.

Through the above method step an “all-side” treatment step is provided whereby all sides of the substrate 2 are subjected to the same treatment. Such an all-side treatment step may be performed in e.g. a single processing chamber for the substrate 2, so that manufacturing complexity is reduced as masking equipment or use of barriers for the substrate 2 are not needed.

Once the stack 10 of the thin oxide layer and polysilicon layer is deposited on all sides 4, 6, 8 of the substrate 2, the method according to this embodiment further comprises the step of subsequently providing a doped layer 12 on the back side 6, the (circumferential) edge 8 and the front side 4 of the substrate 2 through diffusion. The doped layer 12 may be formed by a doped polysilicon layer part of the stack 10. Instead of subsequently doping the polysilicon layer part of the stack 10, the polysilicon layer may also be doped in-situ during deposition of the entire stack 10. Instead of doping by diffusion or in-situ doping, also other doping methods such as implantation may be used (in case of implantation, for reasons of cost-effectiveness only the rear side part of stack 10 would be implanted).

In an embodiment the doped layer 12 may be a p+ or an n+ type doped layer 12. For example, in an embodiment a p+ doped layer 12 may be provided through boron diffusion. In a further embodiment an n+ doped layer 12 may be provided through phosphorous diffusion (e.g. using POCl3). The active dopant concentration of the doped polysilicon layer is in advantageous embodiments above 1E19 cm⁻³, more preferably about 1E20 cm⁻³ or higher, to obtain suitable carrier selective properties.

The method then proceeds with the step of removing the stack 10 of the thin oxide layer and polysilicon layer on the front side 4 (e.g. by an etching step). This step allows the front side of the substrate 2 to be exposed again and ready for further processing, e.g. making front contacts.

According to the present invention, the stack 10 of the thin oxide layer and polysilicon layer provides an excellent barrier so that one or more sides 4, 6, 8 of the substrate 2 can be subjected to one or more all side treatment steps such as an all side diffusion step after which unwanted parts of the resulting stack 10 can be removed at will.

As depicted in FIG. 1C, when the stack 10 is deposited on the back side 6, edge 8, and/or front side 4 of the substrate 2, the applied stack 10 covers (at least in part) the first polarity diffusion layer 4a and prevents degradation thereof during subsequently applied diffusion steps. For example, in case a p+ diffusion layer 4a is present on the front side 4 of the substrate 2, as shown in FIGS. 1a and 1b, the applied stack 10 covers this p+ diffusion layer 4a so that when a doped layer 12 on the front side 4 (and back side 6 and edge 8) is obtained through an all side treatment step, the p+ diffusion layer is preserved and protected against further diffusion. In particular, the front side 4 may comprise a p+ diffusion layer 4a covered by the stack 10, where an n+ diffusion layer (n+ doped layer 12) can be provided in the stack 10 on the back side 6, edge 8 and the front side 4 whilst not affecting the p+ diffusion layer 4a.

FIG. 1D depicts a further step in this exemplary embodiment of the present invention method wherein removing the stack 10 of the thin oxide layer and polysilicon layer on the front side 4 comprises a selective etching step that is preceded by applying an etch barrier 14 to the back side 6 of the substrate 2, e.g. using a plasma enhanced chemical vapour deposition (PECVD) step. The term selective etching step is to be understood that the etching step has different process parameters, such as etching speed or material etching capability, depending of the material encountered. This embodiment provides optional protection for further treatments steps of the doped layer 12 at the back side 6, so that doping and passivation quality of the doped layer 12 at the back side 6 is retained during further processing. E.g., the thickness of the etch barrier 14, in case deposited by PECVD, may be between about 5 nm and 500 nm, e.g. about 100 nm. When the etch barrier is deposited by other means, e.g. a screen printing of a barrier paste, its thickness may be much higher, e.g. several μm.

As a further embodiment (shown in FIG. 1D), the method may further comprise applying an etch barrier 14 to the back side 6 followed by a removal of parasitic etch barrier material from the front side 4. Here the etch barrier 14 applied to the back side 6 may leave parasitic traces on the front side 4, (indicated as barrier part 14a of the etch barrier 14) which in this embodiment may be removed, e.g. using a (short) HF dip step.

Referring to FIG. 1E, in this figure an exemplary embodiment is shown wherein the stack 10 is removed from the front side 4 of the substrate 2. In FIG. 1E it is clearly shown that the earlier removal of the rim surface part 5 of the front side 4 (see the step of FIG. 1B), now prevents immediate electrical connection between the first polarity diffusion layer 4a on the front side 4 and the remaining part of the stack 10, in particular the doped layer 12 applied thereto. As there is no electrical connection between the first polarity diffusion layer 4a and the stack 10, it is possible to obtain a good edge isolation and as a result obtain minimized reverse currents in the solar cell (increasing performance thereof).

In an advantageous embodiment the method step of removing the stack 10 of the thin oxide layer and the polysilicon layer on the front side 4 may further comprise one or more selective etching steps. The selective etching steps will first etch the doped layer 12 and furthermore the polysilicon part of stack 10 and finally the thin oxide layer of the stack 10, at appropriate etching rates matching the material being etched. This method step allows efficient and complete removal of the stack 10 on the front side 4 whilst preserving quality of the first polarity diffusion layer 4a. The selective etching of an n-type doped layer 12 may for example be performed by an etchant comprising diluted TMAH (tetra methyl ammonium hydroxide), which etches a p-type doped layer 4a much more slowly, and also etches the thin oxide of stack 10 much more slowly.

During the step of providing the doped layer 12 to the stack 10 on the back side 6, edge 8 and the front side 4 through diffusion, it may happen that some diffusion occurs through the stack 10 into the first polarity diffusion layer 4a. For example, should the substrate 2 be provided with a p+ diffusion layer 4a, it may be possible that when applying an n+ doped layer 12 to the stack 10 some n+ diffusion or leakage occurs into the p+ diffusion layer 4a. In the event that some contamination occurs of the first polarity diffusion layer 4a, an embodiment is provided wherein the first polarity diffusion layer 4a remaining on the front side 4 after removal of the stack 10 of thin oxide layer and polysilicon layer on the front side 4, is subjected to a further etching step as shown in FIG. 1F. This method step thus allows for further etching of the first polarity diffusion layer 4a once the stack 10 has been removed. Such further etching step removes any leaked doping into the first polarity diffusion layer 4a that can happen e.g. when applying the doped layer 12 to the stack 10. Such further etching step may for example be performed with an acid etching step with an etching solution comprising nitric acid and hydrofluoric acid. The depth of etching in this further etching step is e.g. between 5 nm and 200 nm.

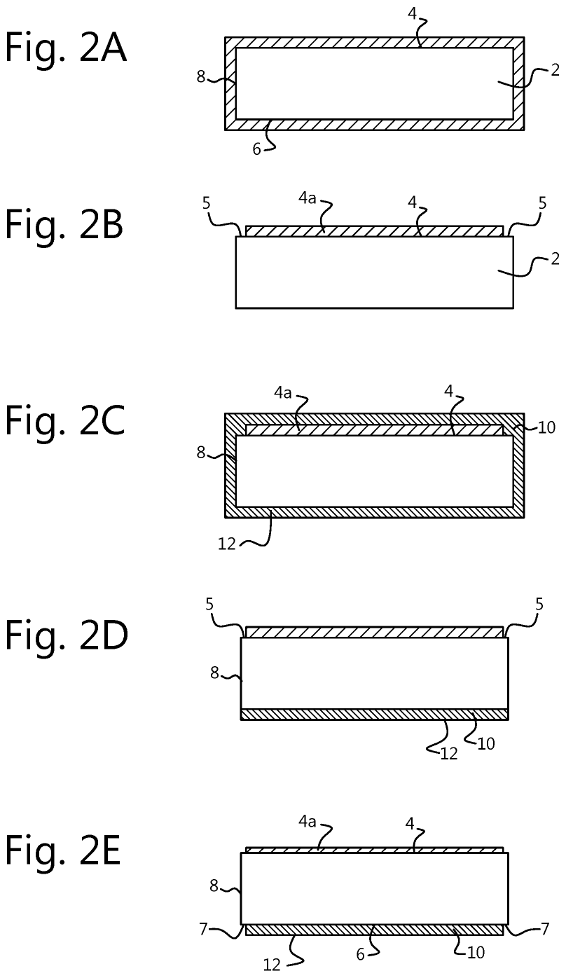

FIGS. 2A to 2E depict a schematic overview of consecutive steps of a further method embodiment. The FIGS. 2A to 2C and the associated method steps are similar to the method steps performed as depicted in the embodiment described above with reference to FIG. 1A to 1C. FIG. 2A shows an embodiment wherein the substrate 2 may be a textured substrate or textured wafer 2. The substrate 2 may be provided with a first polarity diffusion layer 4a on the front side 4 of the substrate 2. In an embodiment the first polarity diffusion layer 4a may be a p+ or n+ type diffusion layer. As depicted the first polarity diffusion layer 4a may be provided to all sides of the substrate 2, i.e. the back side 6, edge 8, and the front side 4, to allow for all side treatment of the substrate 2 to reduce manufacturing complexity.

All method steps prior to applying the stack 10 to the back side 6, edge 8 and front side 4 of the substrate 2 associated with FIGS. 2A and 2B are similar to the method steps as disclosed for FIGS. 1A and 1B. For example, in FIG. 2B an embodiment step is shown similar to FIG. 1B wherein the first polarity diffusion layer 4a is also removed from a rim surface part 5 of the front side 4 of the substrate 6 (again, e.g. with a width of at most 2 mm).

In the further embodiment step as shown in FIG. 2D, the method may comprise a step wherein the stack 10 of the thin oxide layer and the polysilicon layer is further removed from the edge 8 of the substrate. This embodiment provides further electrical isolation or separation between the first polarity diffusion layer 4a and the stack 10, in particular between the first polarity diffusion layer 4a and the stack 10 on the back side 6 of the substrate 2.

FIG. 2E also shows that in this embodiment of the method an additional step is executed wherein the stack 10 of the thin oxide layer and the polysilicon layer is further removed from a rim surface part 7 of the back side 6 of the substrate 2. This removal from the rim surface part 7 of the back side 6 can be accomplished by a controlled creep of the single side etchant onto the back side 6 of the substrate 2, e.g. by adjusting the speed of the movement of the substrate 2 in the single etch tool, by adjusting the liquid level in the single side etch tool, and/or by adjusting the viscosity and surface tension of the etchant. This step may also be performed through e.g. a selective etching procedure after applying an etch barrier 14 (see similar step of FIG. 1D) and yields even further electrical isolation of the first polarity diffusion layer 4a and the stack 10 with respect to the back side 6.

The rim surface part 7 at the back side 6 of the substrate 2 may furthermore be passivated with a passivating coating such as a silicon oxide/silicon nitride stack or an aluminium oxide/silicon nitride stack.

Utilizing a rim surface part 7 of the back side 6 for electrical isolation (for which a width of at most 2 mm is sufficient) may also be possible for the embodiments as shown in e.g. FIGS. 1D to 1F. For example, an embodiment is provided wherein the etch barrier 14 is applied to a part of the back side 6 of the substrate 2. In this embodiment a rim surface part 7 of the back side 6 may be left open from the etch barrier 14 for etching so that the rim surface part 7 may be selectively removed by an etching procedure while shielding the stack 10 applied to the part of the back side 6.

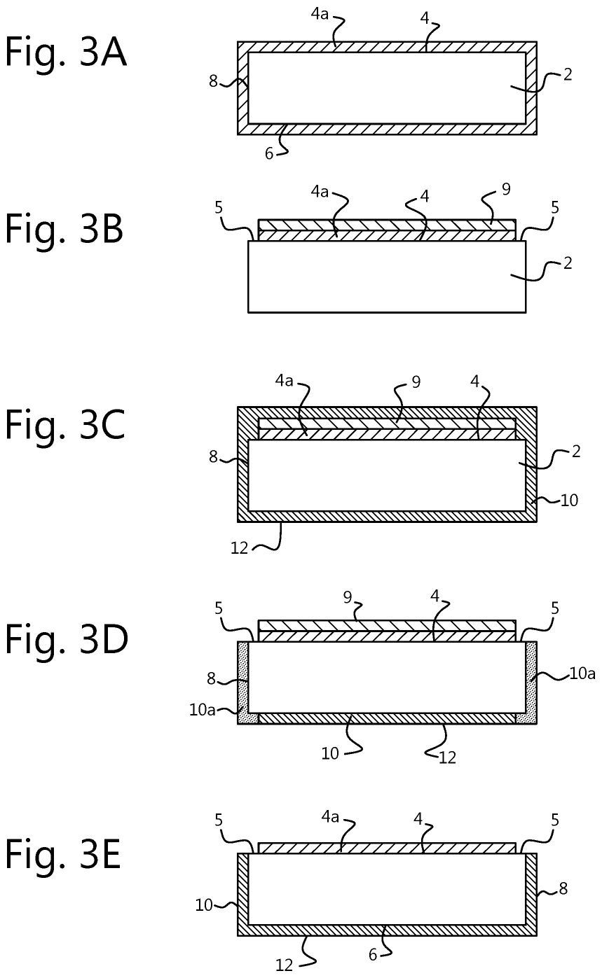

FIGS. 3A to 3E depict a schematic overview of consecutive steps of an even further embodiment of the method according to the present invention. FIG. 3A is associated with method steps that are similar to those used for FIG. 1A and FIG. 2A. That is, FIG. 3A shows an embodiment wherein the substrate 2 may be a textured substrate or textured wafer 2. The substrate 2 may be provided with a first polarity diffusion layer 4a on the front side 4 of the substrate 2. Furthermore, the first polarity diffusion layer 4a may be provided to all sides of the substrate 2, i.e. the back side 6, edge 8, and the front side 4, to allow for all side treatment of the substrate 2 to reduce manufacturing complexity. In an embodiment the first polarity diffusion layer 4a may be a p+ or n+ diffusion layer.

FIG. 3B shows a further possible processing step for an alternative embodiment of the present invention method wherein a barrier layer 9 is provided on the first polarity diffusion layer 4a on the front side 4 before applying the stack 10 of the thin oxide layer and the polysilicon layer. The deposited barrier layer 9 shields the first polarity diffusion layer 4a from removal steps (e.g. etchings steps) during subsequent manufacturing. Note that in FIG. 3B an embodiment is shown similar to FIGS. 1B and 2B wherein the first polarity diffusion layer 4a may also be removed from a rim surface part 5 of the front side 4 (and also the corresponding part of the barrier layer 9 is then removed as shown).

The barrier layer 9 may be obtained in a variety of ways. For example, in case a p+ type diffusion layer 4a is to be provided to the substrate 2 (see FIG. 3A) then a BSG doping layer may be used in conjunction with an annealing step for obtaining a p+ diffusion layer 4a. However, the BSG doping layer need not be removed when the first polarity diffusion layer 4a on the back side 6 and the edge 8 of the substrate 2 is removed, e.g. using a single side etching step. Then as shown in FIG. 3B, a substrate 2 is obtained having a first polarity diffusion layer 4a, i.e. a p+ diffusion layer, covered by the barrier layer 9 comprising the remaining part of the BSG doping layer. Alternatively, the barrier layer 9 can of course be deposited separately before applying the stack 10. The barrier layer 9 enhances the protection of first polarity diffusion layer 4a against indiffusion of dopant from the doping process of stack 10. Further, the barrier layer 9 allows a reduced selectivity of the etching chemistry used for removing stack 10 from the front side 4. In a further embodiment, the barrier layer 9 comprises dopant silicate glass. In an alternative embodiment, the barrier layer 9 comprises a surface passivating layer for the carrier selective contact structure 4a of the first type, such as a layer or layer stack based on thin silicon oxide, aluminium oxide or silicon nitride. In a further advantageous embodiment, the barrier layer 9 is used as a passivating layer and as a base layer of an antireflection coating of the solar cell.

Similar to the method steps associated with FIGS. 1D, 1E and 2D, in FIG. 3D an embodiment step is shown wherein the method step is provided which comprises removal of the stack 10 of the thin oxide layer and the polysilicon layer on the front side 4. A single side etching procedure may be used for this embodiment (similar to the step in FIG. 2D), or a selective etching step with provision of an etch barrier (similar to the steps in FIGS. 1D and 1E).

In a further embodiment, the stack 10 of the thin oxide layer and the polysilicon layer may also be removed from the edge 8 of the substrate 2. In an alternative embodiment, an etch barrier (not shown) may be provided to the back side 6 and optionally to the edge 8, thereby preventing removal of the stack 10 from the back side 6 and edge 8, or only the back side 6, during e.g. an etching procedure. The etch barrier in this embodiment is similarly arranged on the back side 6 and edge 8 as depicted in FIG. 1D before removing the stack 10 from the front side 4. FIG. 3D shows an embodiment where parts 10a of the stack 10 are indicated which may be removed in this etch step. It is noted that here the parts 10a of the stack 10 are on the edges 8, and on the rim surfaces 7 of the back side 6 (see embodiment of FIG. 2E). As a final processing step in this embodiment, the barrier layer 9 on the front side may be removed as shown in FIG. 3E (and in this specific case, the stack 10 is left on the edges 8, providing only the rim surface parts 5 for edge isolation).

The processing steps resulting in the rim surface part 5 on the front side 4 and/or the rim surface part 7 on the back side 6, could be applied in further embodiments for processing a substrate 2, especially for solar cell applications, as the rim surface parts 5, 7 can advantageously provide a very good edge isolation. To this end, the method steps may comprise providing a stack 10 of a thin dielectric material layer and a polysilicon layer (amorphous or polycrystalline silicon) on (at least a part of) the front side 4 and (at least a part of) the back side 6, subsequently removing the polysilicon layer from the front side (and optionally including removing the polysilicon layer from a rim surface part 7 of the back side 6 to enhance isolation in the final device structure), and subsequently creating a selective carrier contact on the front side 4. The selective carrier contact on the front side 4 and the polysilicon layer on the back side 6 can have opposite polarities. One embodiment for the creation of the selective carrier contact on the front side 4 is by implantation of dopants. Another embodiment is to apply a diffusion barrier on the rear side 6, optionally including a rim surface part 5 on the front side 4, followed by diffusion of a dopant into at least the exposed part of the front side 4. Yet another embodiment comprises deposition of a material known for its selective carrier contacting properties on the front side 4, such as titanium oxide, molybdenum oxide, etc. Applying a material on the back side 6 as well as a rim surface part 5 of the front side 4 which masks or inhibits deposition of the front side selective carrier contact, e.g. applying a silylated surface to inhibit ALD, can be used to enhance isolation in an even further embodiment.

After the processing steps as described in this invention, the solar cells may be finished with passivation and anti-reflection coating layers, and metallisation layers and grids, as known in the art.

The present invention has been described above with reference to a number of exemplary embodiments as shown in the drawings. Modifications and alternative implementations of some parts or elements are possible, and are included in the scope of protection as defined in the appended claims.

1. Method for manufacturing a photovoltaic cell from a substrate having a front side, a back side and an edge, the method comprising:
providing a carrier selective contact structure of a first type on at least a part of the front side;
applying a stack having a thin oxide layer covered by a polysilicon layer, wherein the stack is applied to the back side and the front side of the substrate;
removing the stack of thin oxide layer and polysilicon layer on the front side.

2. The method according to claim 1, further comprising providing a doped layer on the back side, edge and front side of the substrate.

3. The method according to claim 1, further comprising providing a doped layer on the back side of the substrate.

4. The method according to claim 1, wherein removing the stack of thin oxide layer and polysilicon layer on the front side comprises a selective etching step preceded by applying an etch barrier to the back side of the substrate.

5. The method according to claim 4, wherein the etch barrier is applied to a part of the back side of the substrate.

6. The method according to claim 4, wherein applying an etch barrier to the back side is followed by a removal of parasitic barrier material from the front side.

7. The method according to claim 1, wherein removing the stack of thin oxide layer and polysilicon layer on the front side comprises a single side etching step.

8. The method according to claim 7, wherein the stack of thin oxide layer and polysilicon layer is further removed from the edge of the substrate.

9. The method according to claim 8, wherein the stack of thin oxide layer and polysilicon layer is further removed from a rim surface part of the back side of the substrate.

10. The method according to claim 1, wherein the thin oxide layer is a thin silicon oxide layer.

11. The method according to claim 1, wherein the carrier selective contact structure of the first type is a first polarity diffusion layer on at least part of the front side, before applying the stack.

12. The method according to claim 11, wherein the first polarity diffusion layer is a p+ diffusion layer.

13. The method according to claim 11, wherein the first polarity diffusion layer on the back side and the edge of the substrate is removed using a single side etching step.

14. The method according to claim 13, wherein the first polarity diffusion layer is also removed using the single side etching step from a rim surface part of the front side of the substrate.

15. The method according to claim 11, wherein a barrier layer is provided on the first polarity diffusion layer on the front side before applying the stack.

16. The method according to claim 11, wherein the first polarity diffusion layer remaining on the front side after removing the stack of thin oxide layer and polysilicon layer on the front side, is subjected to a further etching step.

17. The method according to claim 2, providing the doped layer by diffusion.

18. The method according to claim 11, wherein the carrier selective contact structure of the first type is a first polarity diffusion layer on all sides.
